(19) United States
(12) Patent Application Publication
(10) Pub. No.: US 2003/0011986 A1
(43) Pub. Date: Jan. 16, 2003

(54) Electronic apparatus having a detachable circuit component and method of assembling the electronic apparatus

(76) Inventor: Koji Ariga, Ome-shi (JP)

Correspondence Address: Pillsbury Winthrop LLP, Suite 2800, 725 South Figueroa Street, Los Angeles, CA, 90017-5406, US

(21) Appl. No.: 10/178,690

(22) Filed: Jun. 24, 2002

(30) Foreign Application Priority Data
Jun. 28, 2001 (JP) 2001-196456

(51) Int. Cl. H05K 5/00

(52) U.S. Cl. 361/687; 361/709

(57) ABSTRACT

An electronic apparatus includes a main body containing a circuit component. The main body houses a printed wiring board and a cooling unit that cools the circuit component. The circuit component is detachably mounted on the top surface of the printed wiring board. The cooling unit is detachably mounted on the circuit component. A keyboard is detachably supported by the main body. The keyboard covers the cooling unit.

### CROSS-REFERENCE TO RELATED APPLICATIONS

This application is based upon and claims the benefit of priority from prior Japanese Patent Application No. 2001-196456, filed Jun. 28, 2001.

### BACKGROUND OF THE INVENTION

1. Field of the Invention

The present invention relates to an electronic apparatus including a circuit component that generates heat, such as a microprocessor, and a cooling unit that cools the circuit component. More specifically, the invention relates to a structure that allows a circuit component to be replaced with a new one.

2. Description of the Related Art

A prior art portable computer comprises a main body having a keyboard and a display unit supported by the main body. The main body includes a printed wiring board mounted with a microprocessor, a cooling unit that cools the microprocessor, a battery, a hard disk drive, and a CD-ROM drive.

This type of portable computer can extend its function according to the use thereof. In order to easily change the storage capacity, the power-supply capacity, etc., conventionally, each peripheral device such as a battery, a hard disk drive, and a CD-ROM drive is modularized and can simply be attached to and detached from the main body.

A printed wiring board mounted with basic circuit components such as a microprocessor, a ROM, and a RAM is not originally designed to have the components to be replaceable. If, therefore, an operator has to replace a microprocessor with a higher-performance one, he or she has to disassemble a main body and remove a printed wiring board from the main body. To remove the printed wiring board, the operator has to release a thermal connection between the microprocessor and the cooling unit or an electrical connection between the printed wiring board and another component such as an I/O board. Therefore, a lot of time and effort is required for a preparatory operation to replace the microprocessor.

After the replacement of the microprocessor is completed, the printed wiring board and cooling unit need to be incorporated into the main body and the main body needs to be reassembled into the original condition. Concurrently with this, the printed wiring board is forced to be electrically connected to the other components.

Consequently, in the prior art portable computer, it is very troublesome to replace a basic component such as a microprocessor.

Another prior art portable computer includes a slot where a cartridge having therein a CPU and a cooling unit may be inserted and removed. However, the cartridge having the CPU and cooling unit requires many modifications to be made to a standard printed wiring board within the portable computer, where a socket is normally provided on the standard printed wiring board on which the CPU is mounted. The cartridge having the CPI and cooling unit requires a specialized non-standard configuration that greatly increases the cost of the portable computer, adds complexity to its manufacture, and limits the portable computer to be manufactured as a built-to-order (BTO) system.

### BRIEF SUMMARY OF THE INVENTION

An object of the present invention is to provide an electronic apparatus that is capable of easily replacing a circuit component such as a microprocessor, and having excellent workability of the replacement.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view of a portable computer according to an embodiment of the present invention, in which a keyboard and a keyboard holder are detached from a main body.

FIG. 2 is an exploded perspective view of the portable computer according to the embodiment of the present invention, showing a relationship in position between the main body, microprocessor, and cooling unit.

FIG. 3 is a perspective view of the portable computer according to the embodiment of the present invention, showing the microprocessor that is to be detached from a socket on a printed wiring board.

FIG. 4 is a cross-sectional view of the portable computer according to the embodiment of the present invention, showing a relationship in position between the microprocessor mounted on the printed wiring board, cooling unit, cover, and keyboard.

FIG. 5 is a cross-sectional view of the portable computer according to the embodiment of the present invention, showing a relationship in position between an exhaust hole of a housing and the cooling unit.

### DETAILED DESCRIPTION

An embodiment of the present invention will now be described with reference to the accompanying drawings.

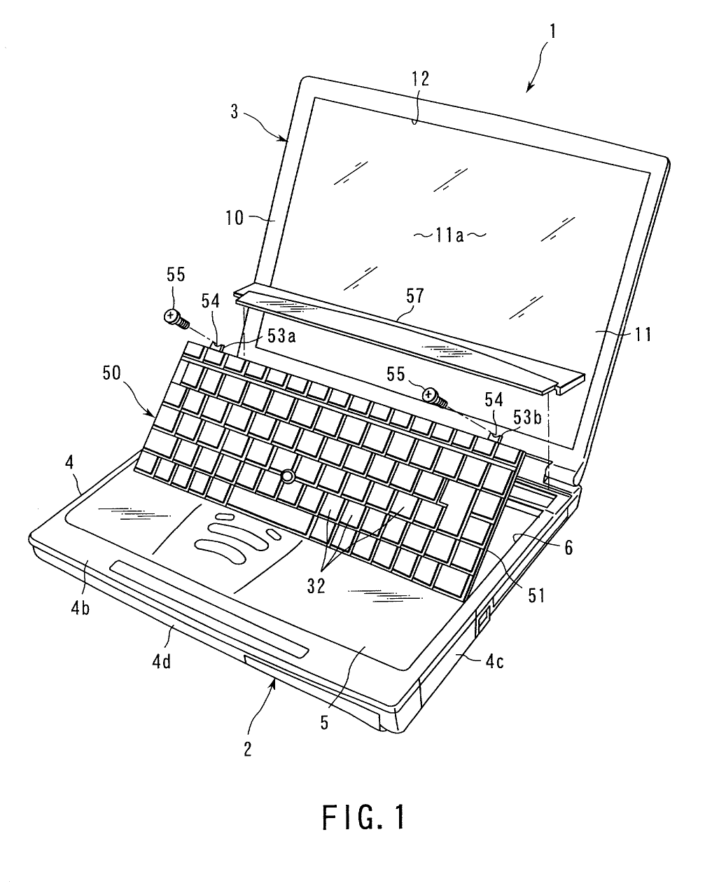

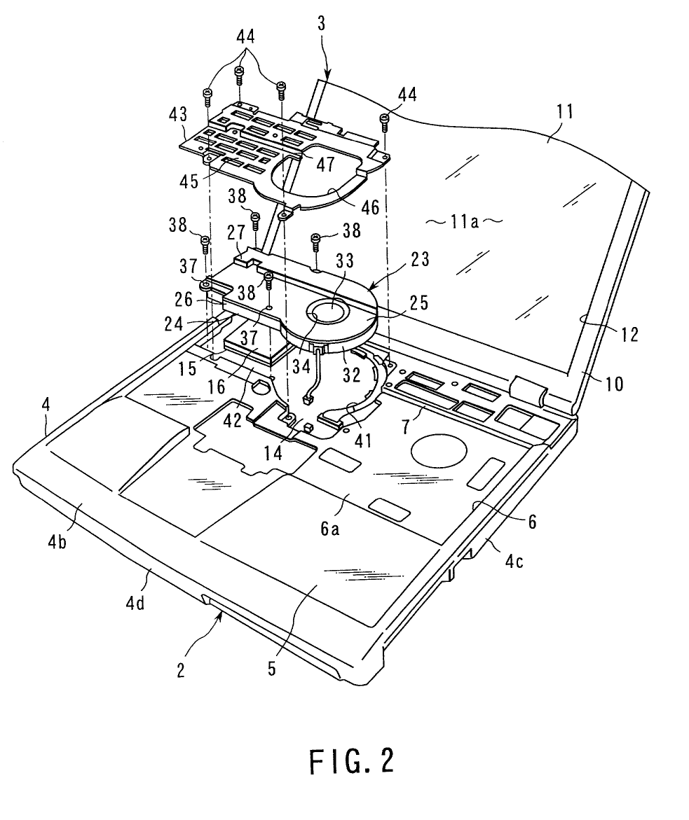

FIG. 1 illustrates a portable computer 1 serving as an electronic apparatus. The portable computer 1 comprises a main body 2 and a display unit 3. The main body 2 includes a flat box-shaped housing 4. The housing 4 has a bottom wall 4a, a top wall 4b, right and left side walls 4c, a front wall 4d, and a rear wall 4e. The top wall 4b includes a palm rest 5 and a keyboard mounting section 6. The palm rest 5 is located in the front half of the housing 4. The keyboard mounting section 6 is located behind the palm rest 5. The section 6 is recessed toward the inside of the housing 4 and has a flat bottom 6a as shown in FIG. 2. The section 6 also has a step portion 7 that rises from the rear of the bottom 6a. The step portion 7 extends in the longitudinal direction of the keyboard mounting section 6.

The display unit 3 includes a display housing 10 and a liquid crystal display 11 contained in the display housing 10. The liquid crystal display 11 has a display screen 11a that displays information. The display screen 11a is exposed outside through an opening 12 that is opened to the front surface of the display housing 10.

The display housing 10 is joined to the rear end of the housing 4 by a hinge device (not shown). The display unit 3 can thus be turned between a closed position where it covers the main body 2 from above and an opened position where it rises to expose the main body 2 and the display screen 11a.

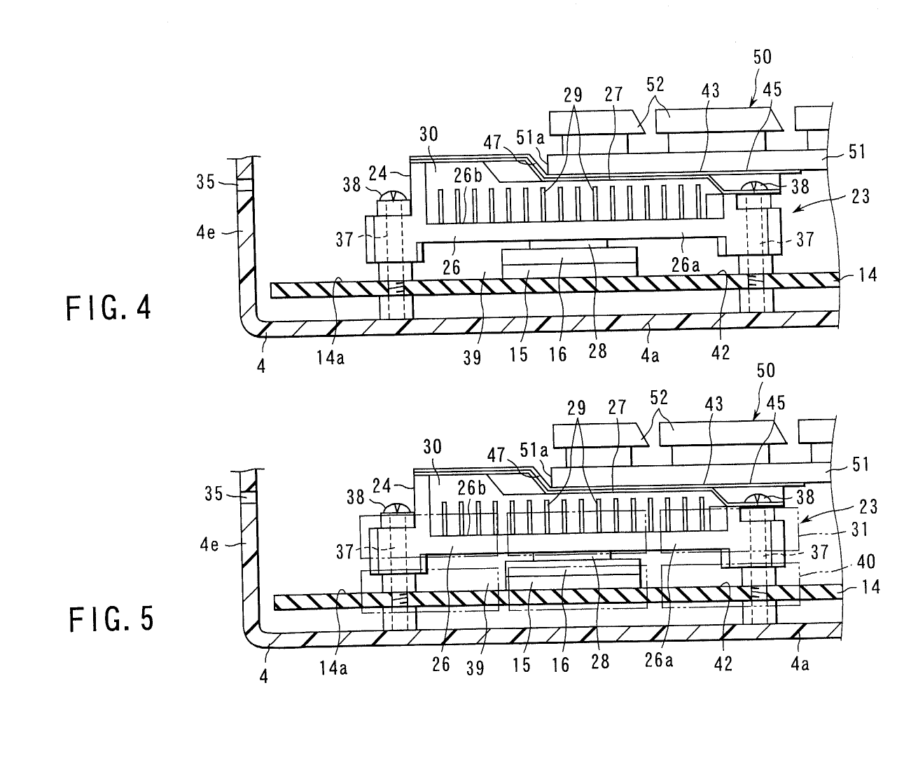

As shown in FIG. 4, the housing 4 houses a printed wiring board 14. The printed wiring board 14 is placed in parallel to the bottom wall 4a of the housing 4 and located under the keyboard mounting section 6. The printed wiring board 14 has a top surface 14a opposed to the keyboard mounting section 6. A socket 15 is mounted on the top surface 14a of the board 14. The socket 15 is located on the left side of the rear end of the printed wiring board 14. A microprocessor 16 is detachably fitted into the socket 15. The microprocessor 16 is a basic circuit component that serves as the center of the portable computer 1 and generates heat during operation.

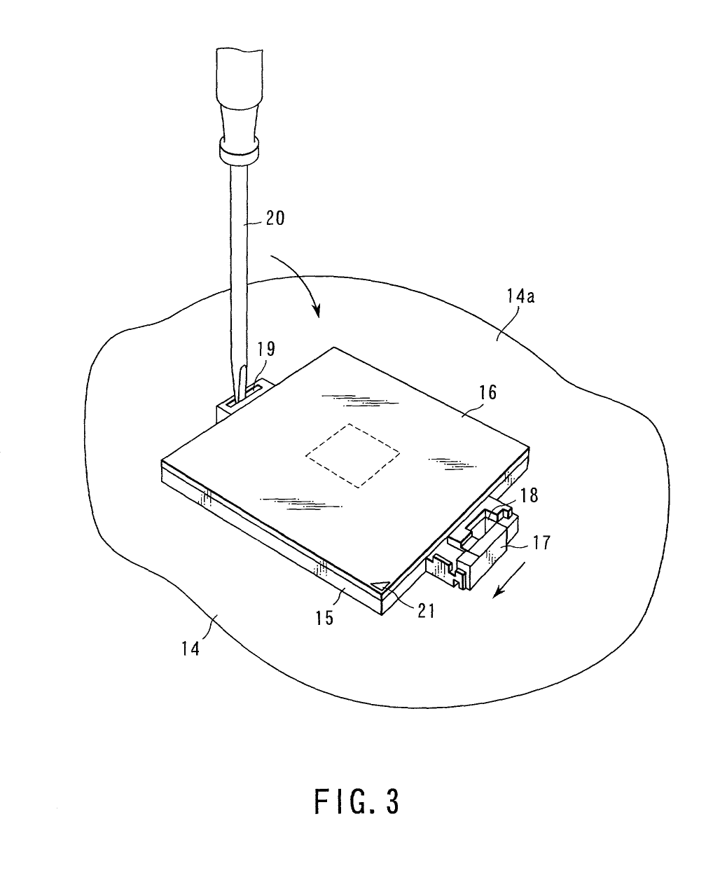

FIG. 3 illustrates the microprocessor 16 that is fitted into the socket 15. The socket 15 has a lock latch 17 and a first slot 18 at one end and a second slot 19 at the opposite end. The first and second slots 18 and 19 are each used to insert a driver 20 thereinto. To remove the microprocessor 16 from the socket 15, the lock latch 17 is first slid to a release position from a lock position as indicated by the arrow in FIG. 3. Then, the driver 20 is inserted into the second slot 19. After that, the driver 20 is tilted toward the microprocessor 16 to shift the microprocessor 16 to the lock latch 17. Thus, the microprocessor 16 and socket 15 are separated from each other and the microprocessor 16 can be removed upward from the socket 15.

In order to fit the microprocessor 16 into the socket 15, the former is overlaid on the latter such that a triangular mark 21 formed at one corner of the microprocessor 16 coincides with one corner of the socket 15. Then, the driver 20 is inserted into the first slot 18. After that, the driver 20 is tilted toward the microprocessor 16 to shift the microprocessor 16 away from the lock latch 17. Thus, the microprocessor 16 and socket 15 are fitted to each other. Finally, the lock latch 17 is slid to the lock position from the release position to fix the microprocessor 16 into the socket 15.

As shown in FIGS. 2 to 4, the housing 4 houses a cooling unit 23. The cooling unit 23 is designed to cool the microprocessor 16. The cooling unit 23 includes a heat sink 24 and an electric fan 25.

The heat sink 24 is placed on the top surface 14a of the printed wiring board 14. The heat sink 24 includes a base 26 and a top board 27 supported at the upper end of the base 26. The base 26 is formed to such a size as to cover the microprocessor 16 from above. The base 26 has a bottom surface 26a and a top surface 26b. The bottom surface 26a of the base 26 is opposed to the microprocessor 16 and the printed wiring board 14. Thermal-conductivity grease 28 is interposed between the bottom surface 26a of the base 26 and the microprocessor 16. The grease 28 thermally connects the base 26 and the microprocessor 16 to each other. Heat of the microprocessor 16 is therefore transferred to the base 26 and the top board 27 through the grease 28.

A cooling air passage 30 is formed between the top board 27 and the top surface 26b of the base 26. The passage 30 extends along the width direction of the housing 4. The base 26 has a plurality of cooling fins 29 that protrude from the top surface 26b of the base 26. The cooling fins 29 are arranged in the cooling air passage 30. The downstream end of the passage 30 communicates with a plurality of first exhaust holes 31 (shown in FIG. 5) that are opened to the left sidewall 4c of the housing 4.

The electric fan 25 includes a fan casing 32 and a centrifugal impeller 33 cased in the fan casing 32. The fan casing 32 is located at the right end portion of the heat sink 24 and formed integrally with the heat sink 24 as one component. The fan casing 32 has an inlet 34 and an outlet (not shown). The inlet 34 is located close to a suction port 35 that is opened to the rear wall 4e of the housing 4. The outlet communicates with the upstream end of the cooling air passage 30.

When the impeller 33 rotates, air is inhaled into the housing 4 from outside through the suction port 35. The air is inhaled into the inlet 34 together with the internal air of the housing 4 and exhaled into the fan casing 32 from the outer peripheral portion of the impeller 33. The exhaled air is transferred to the cooling air passage 30 through the outlet as cooling air. The cooling air passes between the cooling fins 29 and flows through the cooling air passage 30 to cool the heat sink 24. The heat of the microprocessor 16 transferred to the heat sink 24 is lost by heat exchange with the cooling air. The air heated by the heat exchange is exhaled from the housing 4 through the first exhaust holes 31.

As illustrated in FIG. 2, the heat sink 24 includes four mounting holes 37. The mounting holes 37 are formed along the thickness direction of the housing 4 and penetrate the heat sink 24. First screws 38 are inserted into their respective mounting holes 37. The first screws 38 penetrate the heat sink 24 and printed wiring board 14 and are screwed into the bottom wall 4a of the housing 4. In this embodiment, coil springs (not shown) are attached to their respective outer peripheral portions of the first screws 38. The coil springs are interposed between the printed wiring board 14 and the heat sink 24.

The cooling unit 23 including the heat sink 24 can be moved in a direction close to and distant from the microprocessor 16 using the first screws 38 as a guide.

The cooling unit 23 is always elastically energized in a direction distant from the microprocessor 16 by the coil springs. The housing 4 therefore supports the cooling unit 23 in a floating manner to prevent an excessive pressure from being applied to the microprocessor 16.

When the cooling unit 23 is supported by the housing 4 as shown in FIG. 4, an air guide passage 39 is formed between the bottom surface 26a of the heat sink 24 and the top surface 14a of the printed wiring board 14. The air guide passage 39 is located under the cooling air passage 30. The microprocessor 16 is exposed to the air guide passage 39. The left end of the air guide passage 39 communicates with a plurality of second exhaust holes 40 (shown in FIG. 5) that are opened to the left side wall 4c of the housing 4.

The second exhaust holes 40 are located under the above first exhaust holes 31.

As shown in FIG. 2, the cooling unit 23 is located under the left end portion of the keyboard mounting section 6. An opening 41 for exposing the cooling unit 23 is formed in the bottom 6a of the keyboard mounting section 6. The opening 41 is formed to such a size as to insert and remove the cooling unit 23 into and from the housing 4. The opening 41 is formed above the printed wiring board 14. Thus, the printed wiring board 14 has a mounting region 42 opposed to the opening 41, and the microprocessor 16 is fitted into the mounting region 42 through the socket 15.

The opening 41 of the keyboard mounting section 6 is covered with a metallic cover 43 from above. The cover 43 is shaped like a plate and formed to such a size as to match the shape of the opening 41. The cover 43 is detachably fixed on the bottom 6a of the keyboard mounting section 6 through four second screws 44. The cover 43 faces the foregoing cooling unit 23 and serves as a stopper to prevent the cooling unit 23 from moving upwards.

The cover 43 has a bearing surface 45, a through hole 46 and a guide section 47. The bearing surface 45 is flush with the bottom 6a of the keyboard mounting section 6. The through hole 46 is made in the bearing surface 45 and opposed to the inlet 34 of the fan casing 32. The guide section 47 is formed by bending the cover 43. The guide section 47 protrudes upward through the bearing surface 45 and continues to the step portion 7 of the keyboard mounting section 6.

As shown in FIG. 1, a keyboard 50 is detachably mounted on the keyboard mounting section 6. The keyboard 50 includes a keyboard panel 51 and a plurality of key tops 52 supported by the keyboard panel 51. The keyboard panel 51 is shaped like a rectangle to such a size as to fit into the keyboard mounting section 6 and overlaid on the bottom 6a of the keyboard mounting section 6 and the bearing surface 45 of the cover 43. The keyboard 50 is detachably connected to the printed wiring board 14 via a flexible cable (not shown). A node between the flexible cable and the printed wiring board 14 is located at the front end of the keyboard mounting section 6.

The keyboard panel 51 has a trailing edge 51a extending in the longitudinal direction of the panel. The trailing edge 51a is caught in the step portion 7 and the guide section 47 of the cover 43 when the keyboard panel 51 is mounted on the keyboard mounting section 6. The mounting position of the keyboard 50 on the keyboard mounting section 6 is therefore fixed.

A pair of tongue pieces 53a and 53b is formed at the trailing edge 51a of the keyboard panel 51. The tongue pieces 53a and 53b are arranged separately from each other in the longitudinal direction of the keyboard panel 51 and protrude from the rear of the keyboard panel 51. The tongue pieces 53a and 53b are overlaid on the bearing surface 45 of the cover 43 and the bottom 6a of the keyboard mounting section 6 when the keyboard 50 is mounted on the keyboard mounting section 6. The tongue pieces 53a and 53b have mounting holes 54, respectively. The mounting holes 54 are each made by cutting the trailing edge of the tongue piece like a letter “U”.

Third screws 55 are inserted into their respective mounting holes 54 of the tongue pieces 53a and 53b. The third screws 55 are screwed into the cover 43 and the bottom 6a of the keyboard mounting section 6. With these screws, the keyboard panel 51 of the keyboard 50 is pressed on the bottom 6a of the keyboard mounting section 6 and the bearing surface 45 of the cover 43.

As shown in FIG. 1, a keyboard holder 57 is detachably fitted to the rear end portion of the keyboard mounting section 6. The keyboard holder 57 is shaped like a band extending in the longitudinal direction of the keyboard panel 51. The keyboard holder 57 covers the tongue pieces 53a and 53b and third screws 55 from above. The trailing edge 51a of the keyboard panel 51 is interposed between the keyboard holder 57 and the bottom 6a of the keyboard mounting section 6.

A procedure for replacing the microprocessor 16 contained in the main body 2 will now be described.

Referring to FIG. 1, the display unit 3 is first turned to the opened position from the closed position to expose the keyboard 50 on the housing 4. Then, the keyboard holder 57 is detached from the keyboard mounting section 6 to expose the tongue pieces 53a and 53b of the keyboard panel 51 and third screws 55. After that, the third screws 55 are loosened and removed to release the keyboard 50 from the keyboard mounting section 6. Then, the keyboard 50 is raised and removed from the keyboard mounting section 6, and the flexible cable of the keyboard 50 is disconnected from the printed wiring board 14. The keyboard 50 can thus be separated from the main body 2.

When the keyboard 50 need not be separated from the main body 2, it is turned inside out while the flexible cable is connected to the printed wiring board 14. The turned keyboard 50 may be placed on the palm rest 5, for example.

If the keyboard 50 is removed from the keyboard mounting section 6, the bottom 6a of the keyboard mounting section 6, cover 43, and second screws 44 are exposed. In this state, the second screws 44 are loosened and removed, with the result that the cover 43 can be released from the keyboard mounting section 6 and removed therefrom. Consequently, the opening 41 in the bottom 6a of the keyboard mounting section 6 is exposed and so are the connecting unit 23 and first screws 38 through the opening 41.

Then, the first screws 38 are loosened and removed to release the cooling unit 23 from the housing 4. The cooling unit 23 is removed from the opening 41 to the outside of the housing 4. Thus, the mounting region 42 of the printed wiring board 14 and the microprocessor 16 are exposed to the outside of the housing 4 through the opening 41.

As illustrated in FIG. 3, the lock latch 17 of the socket 15 is slid to the release position from the lock position. Concurrently with this, the driver 20 is inserted into the second slot 19 of the socket 15 and tilted to shift the microprocessor 16 toward the lock latch 17. Consequently, the microprocessor 16 and socket 15 are disconnected from each other, with the result that the microprocessor 16 can be removed outside the housing 4.

As described above, in order to remove the microprocessor 16 from the printed wiring board 14, the keyboard 50, cover 43 and cooling unit 23 have only to be removed in sequence from the housing 4. It is thus unnecessary to perform a troublesome operation of disassembling the housing 4 and removing the printed wiring board 14 from inside the housing 4.

When the existing microprocessor 16 is removed completely, a new microprocessor 16 is mounted on the socket 15 on the printed wiring board 14. This mounting operation is carried out according to the following procedure.

When the existing microprocessor 16 is removed, the mounting region 42 of the printed wiring board 14 and the socket 15 are exposed to the outside of the housing 4 through the opening 41. Thus, a new microprocessor 16 is first overlaid on the socket 15 through the opening 41. Then, the driver 20 is inserted in the first slot 18 of the socket 15 and tilted to shift the microprocessor 16 in a direction distant from the lock latch 17. Consequently, the microprocessor 16 and the socket 15 are coupled to each other, and the microprocessor 16 is electrically connected to the printed wiring board 14 through the socket 15. After that, the lock latch 17 is slid to the lock position from the release position to fix the microprocessor 16 to the socket 15.

Then, the grease 28 is applied to the central part of the top surface of the microprocessor 16. The heat sink 24 of the cooling unit 23 is placed on the microprocessor 16 and attached to the bottom wall 4a of the housing 4 by the first screws 38. As a result, the heat sink 24 can be moved in a direction close to and distant from the microprocessor 16 using the first screws 38 as a guide and always elastically energized in a direction distant from the microprocessor 16 by the coil springs.

When the cooling unit 23 is attached to the housing 4, the grease 28 is inserted between the microprocessor 16 and the bottom surface 26a of the heat sink 24. Thus, the microprocessor 16 and the heat sink 24 are thermally connected to each other to form a thermal conductive path extending from the microprocessor 16 to the heat sink 24.

Then, the opening 41 of the keyboard mounting section 6 is covered with the cover 43. The cover 43 is fixed to the bottom 6a of the keyboard mounting section 6 by the second screws 44. Thus, the cooling unit 23 is covered with the cover 43 from above and the bearing surface 45 of the cover 43 is flush with the bottom 6a of the keyboard mounting section 6.

Then, the keyboard 50 is turned inside out and placed on the palm rest 50 to electrically connect the flexible cable to the printed wiring board 14. After that, the keyboard panel 51 is fitted into the keyboard mounting section 6 and their tongue pieces 53a and 53b are fixed to the cover 43 and the bottom 6a of the keyboard mounting section 6 by the third screws 55. This fixation allows the keyboard panel 51 to contact the bearing surface 45 of the cover 43 and the bottom 6a of the keyboard mounting section 6. It is thus possible to inhibit a rebound phenomenon of the keyboard 50 from occurring when an operator depresses the key tops 52 by the fingers.

Finally, the keyboard holder 57 is fitted to the rear end portion of the keyboard mounting section 6. The keyboard holder 57 covers the tongue pieces 53a and 53b and third screws 55, and the trailing edge 51a of the keyboard panel 51 is interposed between the keyboard holder 57 and the bottom 6a of the keyboard mounting section 6. Consequently, the keyboard 50 is fixed to the keyboard mounting section 6, and the mounting operation of the new microprocessor 16 is completed.

According to the portable computer 1 so configured, the microprocessor 16 housed in the housing 4 can be replaced with a new one only by removing the keyboard 50 from the keyboard mounting section 6. For this reason, when the function of the portable computer 1 needs to be expanded, a complicated operation for disassembling the housing 4 is not required at all. Consequently, the microprocessor 16 can easily be replaced and the workability of the replacement is improved.

According to the above configuration of the computer, heat of the microprocessor 16 is diffused into the heat sink 24 through the grease 28 and discharged outside the housing 4 from the first exhaust holes 31 by the flow of cooling air. In addition, the radiant heat of the microprocessor 16 is discharged outside the housing 4 through the second exhaust holes 40 from the air guide passage 39 formed between the heat sink 24 and the printed wiring board 14.

Consequently, the microprocessor can be cooled with efficiency, and accordingly, the operating environment of the microprocessor 16 can be kept at an appropriate temperature.

In the foregoing embodiment, the housing supports the cooling unit in a floating manner. However, the present invention is not limited to this configuration. The cooling unit can rigidly be fixed to the housing and, in this case, no cover for restricting the upward movement of the cooling unit is required.

The electronic apparatus of the present invention is not limited to a portable computer. It can be applied to other mobile and digital equipment such as a PDA (Personal Digital Assistant).

The circuit components that generate heat are not limited to a microprocessor. For example, an SDRAM having a DDR (Double Data Rate) mode may be a circuit component.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electronic apparatus, comprising:
a main body;
a printed wiring board housed in the main body and having a top surface;
a circuit component detachably mounted on the top surface of the printed wiring board and generates heat during operation;
a cooling unit thermally connected to the circuit component and detachably mounted on the circuit component; and
a keyboard detachably supported by the main body and covering the cooling unit.

2. The electronic apparatus according to claim 1, wherein the main body includes a keyboard mounting section on which the keyboard is detachably mounted, the cooling unit is located within the main body, and the main body has an opening through which the cooling unit is inserted and removed.

3. The electronic apparatus according to claim 1, wherein the cooling unit elastically moves in a direction close to and distant from the circuit component.

4. The electronic apparatus according to claim 1, wherein the cooling unit includes a heat sink having a cooling air passage and an electric fan that blows cooling air, and the circuit component is thermally connected to the heat sink.

5. The electronic apparatus according to claim 4, wherein the heat sink has a bottom surface opposed to the top surface of the printed wiring board, a guide passage is formed between the bottom surface of the heat sink and the top surface of the printed wiring board, and the circuit component is located in the guide passage.

6. The electronic apparatus according to claim 1, wherein the circuit component is a microprocessor, and the printed wiring board has a socket that detachably supports the microprocessor.

7. An electronic apparatus, comprising:
a main body containing a printed wiring board;
a keyboard detachably supported by the main body;
a cooling unit detachably housed in the main body, wherein at least part of the cooling unit is covered by the keyboard; and
a circuit component detachably mounted on the printed wiring board that generates heat during operation and is cooled by the cooling unit, wherein at least part of the circuit component is covered by the cooling unit.

8. The electronic apparatus according to claim 7, wherein the cooling unit elastically moves in a direction close to and distant from the circuit component.

9. The electronic apparatus according to claim 7, wherein the cooling unit includes a heat sink having a cooling air passage and an electric fan that blows cooling air, and the circuit component is thermally connected to the heat sink.

10. The electronic apparatus according to claim 9, wherein the heat sink has a bottom surface opposed to the top surface of the printed wiring board, a guide passage is formed between the bottom surface of the heat sink and the top surface of the printed wiring board, and the circuit component is located in the guide passage.

11. The electronic apparatus according to claim 7, wherein the circuit component is a microprocessor, and the printed wiring board has a socket that detachably supports the microprocessor.

12. An electronic apparatus, comprising:
a main body containing a printed wiring board;
a keyboard detachably supported by the main body;
a cooling unit detachably housed in the main body, wherein at least part of the cooling unit is located under the keyboard;
a cover that covers the cooling unit and is detachably supported by the main body, wherein at least part of the cover is covered by the keyboard; and
a circuit component detachably mounted on the printed wiring board that generates heat during operation and is cooled by the cooling unit, wherein at least part of the circuit component is covered by the cooling unit.

13. The electronic apparatus according to claim 12, wherein the main body includes a keyboard mounting section on which the keyboard is detachably mounted, the keyboard mounting section is located on the cooling unit and has an opening through which the cooling unit is inserted and removed, and the cover covers the opening.

14. The electronic apparatus according to claim 12, wherein the cover has a bearing surface on which the keyboard is overlaid and a guide section that defines a position of the keyboard relative to the main body by being caught in a trailing edge of the keyboard.

15. A method of assembling an electronic apparatus having a cooling unit that cools a circuit component that generates heat during operation, the method comprising:
detachably mounting the circuit component on a printed wiring board contained in a main body;
detachably housing the cooling unit in the main body, covering at least part of the circuit component with the cooling unit, and thermally connecting the cooling unit to the circuit component; and
detachably mounting a keyboard on the main body and covering at least part of the cooling unit with the keyboard.

16. The method according to claim 15, wherein prior to housing the cooling unit in the main body, applying thermally-conductive grease to the circuit component, and the grease thermally connects the circuit component and the cooling unit to each other.

17. A method of assembling an electronic apparatus having a cooling unit that cools a circuit component that generates heat during operation, the method comprising:
detachably mounting the circuit component on a printed wiring board contained in a main body;
detachably housing the cooling unit in the main body, covering at least part of the circuit component with the cooling unit, and thermally connecting the cooling unit to the circuit component;
detachably attaching a cover to the main body and covering the cooling unit with the cover; and
detachably mounting a keyboard on the main body and covering at least part of the cover with the keyboard.

18. An electronic apparatus containing a circuit component that generates heat during operation, comprising:
a main body having a top wall;
a keyboard detachably supported by the top wall of the main body; and
a printed wiring board housed in the main body and having a region exposed to an outside of the main body when the keyboard is removed from the top wall of the main body, wherein the circuit component is detachably mounted on the region.

19. An electronic apparatus containing a circuit component that generates heat during operation, comprising:
a main body having a top wall;
a keyboard detachably supported by the top wall of the main body;
a printed wiring board housed in the main body and having a region exposed to an outside of the main body when the keyboard is removed from the top wall of the main body, wherein the circuit component is detachably mounted on the region; and
a cooling unit that cools the circuit component and is detachably housed in the main body and exposed to the outside of the main body when the keyboard is detached from the top wall of the main body.

20. The electronic apparatus according to claim 19, wherein the top wall of the main body includes a keyboard mounting section on which the keyboard is detachably mounted, which is located on the cooling unit and has an opening through which the cooling unit is inserted and removed.

21. An electronic apparatus, comprising:
a main body;
a printed wiring board housed in the main body and having a top surface;
a circuit component detachably mounted on the top surface of the printed wiring board; and
a keyboard detachably supported by the main body and covering the circuit component.

22. The electronic apparatus according to claim 21, further including a cooling unit thermally connected to the circuit component and detachably mounted on the circuit component.

23. The electronic apparatus according to claim 21, wherein the circuit component is a microprocessor, and the printed wiring board has a socket that detachably supports the microprocessor.
